(19) United States
(12) Patent Application Publication
(10) Pub. No.: US 2026/0223420 A1
(43) Pub. Date: Jul. 30, 2026

(54) SEMICONDUCTOR DEVICE

(71) Applicant: Micron Technology, Inc., Boise, ID (US)

(72) Inventor: Akiyoshi Seko, Hiroshima (JP)

(73) Assignee: Micron Technology, Inc., Boise, ID (US)

(21) Appl. No.: 19/449,042

(22) Filed: Jan. 14, 2026

Related U.S. Application Data
(60) Provisional application No. 63/749,130, filed on Jan. 24, 2025.

(51) Int. Cl. H10D 62/10; H10B 80/00; H10D 62/60; H10D 80/30; H10D 84/85; H10W 20/20; H10W 90/00; H10W 90/20

(52) U.S. Cl. CPC H10D 62/124; H10B 80/00; H10D 62/60; H10D 80/30; H10D 84/85; H10W 20/213; H10W 20/216; H10W 90/297; H10W 90/7295

(57) ABSTRACT

An apparatus includes: a substrate having first conductivity type; a through-silicon via going through from the top surface to the bottom surface of the substrate; an insulating film surrounding a side surface of the through-silicon via; a first well having second conductivity type in a top portion of the substrate; and a second well having first conductivity type just below the first well in the substrate; wherein one side of the first well and the second well is substantially in contact with the insulating film.

### CROSS-REFERENCE TO RELATED APPLICATIONS

This application claims the filing benefit of U.S. Provisional Application No. 63/749,130, filed January 24, 2025. This application is incorporated by reference herein in its entirety and for all purposes.

### BACKGROUND

For example, with respect to semiconductor devices exemplified by a dynamic random access memory (DRAM), a single semiconductor device may be obtained by stacking and mutually connecting a plurality of semiconductor chips to one another for the purpose of improving integration degree, achieving high bandwidth, etc. The semiconductor chips are mutually connected to one another, for example, by through-silicon vias (TSVs).

### BRIEF DESCRIPTION OF THE DRAWINGS

FIG. 1 is a longitudinal sectional view showing a schematic configuration of a semiconductor device according to an embodiment;

FIG. 2 is a longitudinal sectional view showing the schematic configuration of the semiconductor device according to the embodiment; and

FIG. 3 is a diagram showing a schematic configuration for describing an advantageous effect of the semiconductor device according to the embodiment.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

A semiconductor device according to an embodiment will be described hereunder with reference to the drawings. In the following description, a stack type semiconductor memory device in which DRAM chips are stacked will be described as an example of a semiconductor device. In the description of the embodiment, common or related elements or substantially identical elements are given the same reference signs, and description thereof will be omitted. In the following drawings, the dimensions and dimensional ratios of respective parts in each drawing may not necessarily be the same as the dimensions and dimensional ratios in the embodiment.

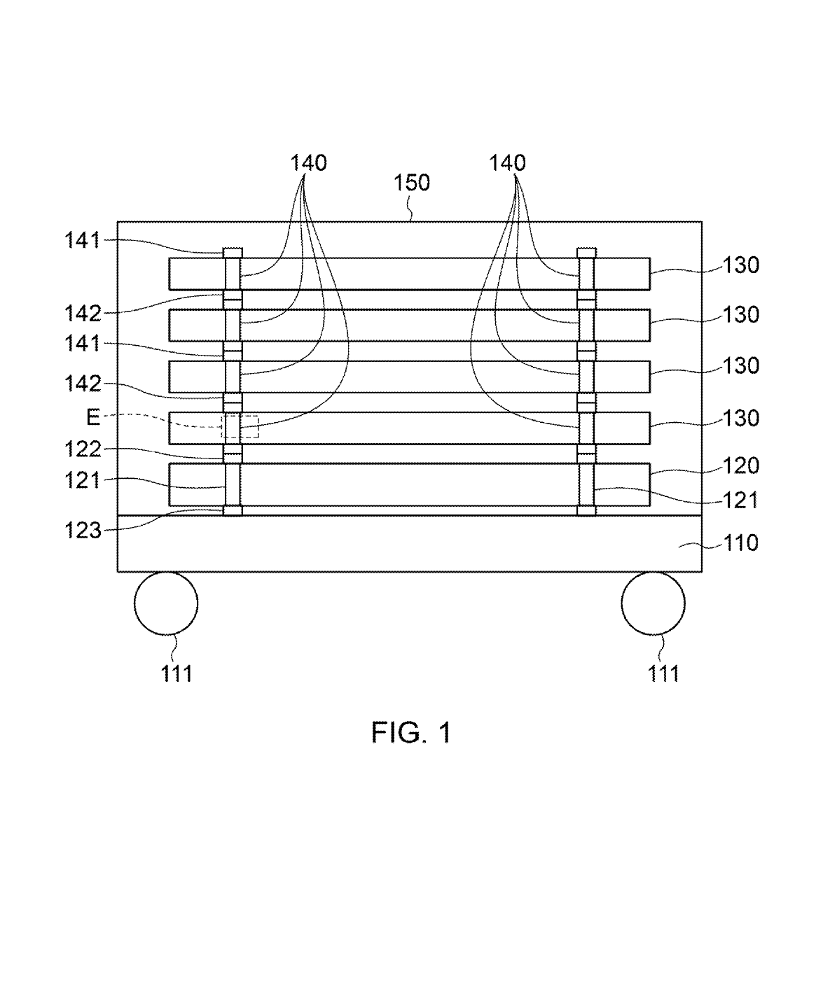

FIG. 1 is a diagram showing an overall configuration of a stack type semiconductor device 1 according to an embodiment.

As shown in FIG. 1, the semiconductor device 1 includes an interposer substrate 110, an interface chip 120 mounted on the top surface of the interposer substrate 110, and a plurality of core chips 130 stacked on the interface chip 120. FIG. 1 shows an example in which four core chips 130 are stacked. External terminals 111 are provided on the bottom surface of the interposer substrate 110. The interface chip 120 and the plurality of core chips 130 are covered with a sealing body 150. The sealing body 150 contains a resin material such as epoxy resin.

The interface chip 120 is provided with a plurality of TSVs 121. The TSVs 121 penetrate through the interface chip 120 from the upper surface of the interface chip 120 to the lower surface thereof. An upper terminal 122 and a lower terminal 123 are provided above and below the TSV 121. Each core chip 130 is provided with a plurality of TSVs 140. The TSVs 140 penetrate through the core chip 130 from the upper surface of the core chip 130 to the lower surface thereof. An upper terminal 141 and a lower terminal 142 are provided above and below the TSV 140. The interface chip 120 has a function of adjusting the bandwidth of an external circuit for controlling the operation of the semiconductor device 1 and the bandwidth of the plurality of core chips 130. The interface chip 120 and the core chip 130 are connected to each other by contacting the upper terminals 122 of the interface chip 120 with the lower terminals 142 of the core chip 130 mounted on the upper terminals 122.

Each core chip 130 is, for example, a DRAM chip including a plurality of memory cells provided on a semiconductor substrate. The TSV 140 penetrates through the core chip 130 from the upper surface of the core chip 130 to the lower surface thereof in an up-down direction. An upper terminal 141 and a lower terminal 142 are provided above and below the TSV 140. The plurality of core chips 130 are stacked in the up-down direction such that the respective upper terminals 141 and lower terminals 142 thereof are connected to each other.

Control signals from an external circuit for controlling the semiconductor device 1 and data signals output from the semiconductor device 1 are transmitted and received via the external terminals 111. The external terminals 111 and the interface chip 120 are connected to each other by wirings (not shown). Control signals such as an address, a command, and write data to be supplied from the external circuit to the respective core chips 130 via the external terminals 111 are supplied to the respective core chips 130 via the upper terminals 122 and 141, the lower terminals 123 and 142, and the TSVs 121 and 140 provided on the core chips 130. These control signals are divided and reduced in bandwidth by the interface chip 120, and transferred to each core chip 130. Data signals from each core chip 130 are aggregated by the core chip 130 to be converted to a wideband band, and then output to the outside via the external terminals 111.

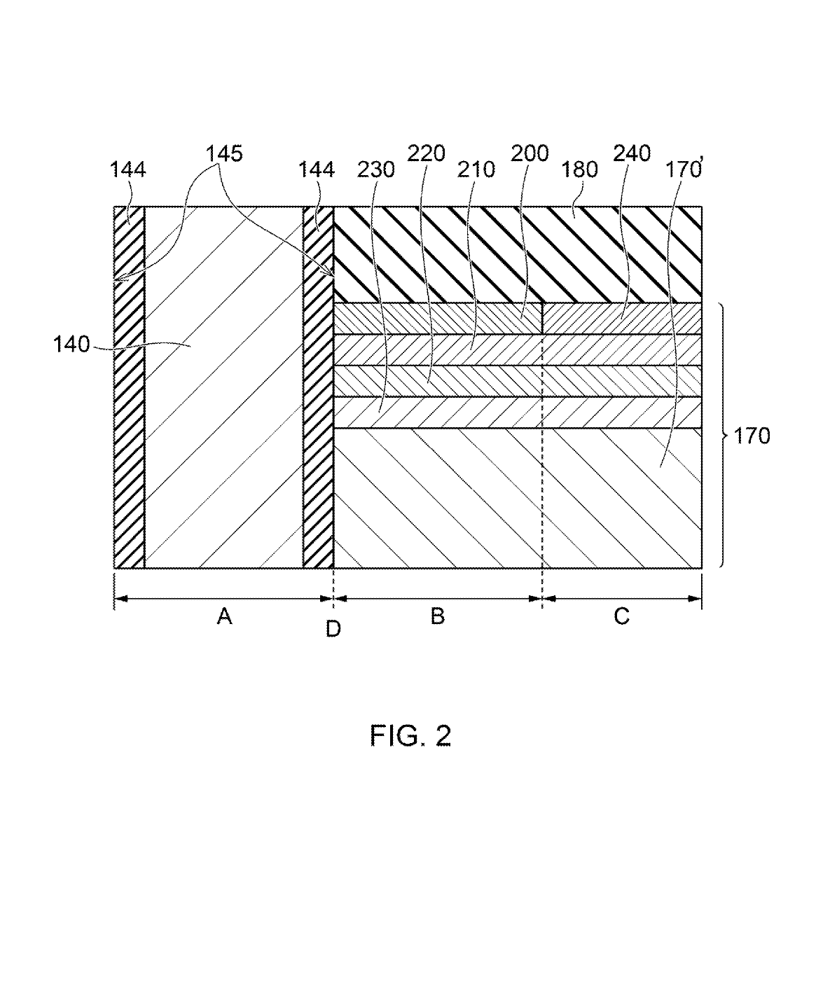

FIG. 2 is an enlarged longitudinal sectional view of a portion E shown in FIG. 1. As shown in FIG. 2, the core chip 130 of the embodiment includes a semiconductor substrate 170 and a TSV 140. A second insulating portion 180 is provided on the semiconductor substrate 170. The semiconductor substrate 170 contains, for example, single crystal silicon. The semiconductor substrate 170 contains, for example, P-type impurities having a concentration of about 1.0×10¹⁴ atoms/cm³. For example, Boron (B) is contained as the P-type impurities. The TSV 140 contains, for example, a conductive material such as copper (Cu). The first insulating portion 144 and the second insulating portion 180 contain, for example, an insulating material such as silicon dioxide (SiO₂).

A first region A and a second region B adjacent to the first region A are arranged in the semiconductor substrate 170, and a third region C is further arranged to be adjacent to the second region B. The second region B is sandwiched between the first region A and the third region C. A boundary D indicates the boundary between the first region A and the second region B. The second region B includes a first well 200, a second well 210, a third well 220, and a fourth well 230. The third region C includes a fifth well 240, a second well 210, a third well 220, and a fourth well 230. In other words, the second well 210, the third well 220, and the fourth well 230 are arranged in the second region B and the third region C so as to extend through the second region B and the third region C.

The TSV 140 and the first insulating portion 144 are provided in the first region A. The TSV 140 has a cylindrical shape, and penetrates the semiconductor substrate 170 and the second insulating portion 180 provided on the top surface of the semiconductor substrate 170. The first insulating portion 144 is provided around the TSV 140. The TSV 140 and the semiconductor substrate 170 are insulated from each other by the first insulating portion 144.

The first well 200, the second well 210, the third well 220, and the fourth well 230 are provided in the second region B adjacent to the first region A. The first well 200, the second well 210, the third well 220, and the fourth well 230 are arranged in this order to go downwards from the top portion of the semiconductor substrate 170. The first well 200 is provided at the top portion of the semiconductor substrate 170. The second well 210 is sandwiched between the first well 200 and the third well 220. The third well 220 is sandwiched between the second well 210 and the fourth well 230.

The fifth well 240 is disposed to be adjacent to the first well 200 in the third region C adjacent to the second region B. In FIG. 2, the TSV 140 is disposed on the left side of the first well 200, and the fifth well 240 is disposed on the right side of the first well 200. The fifth well 240 is provided at the top portion of the semiconductor substrate 170. Below the fifth well 240, the second well 210, the third well 220, and the fourth well 230 are arranged so as to go downwards in this order.

The first well 200 and the second well 210 are wells having N-type conductivity, and are doped with N-type impurities such as phosphorus. The third well 220, the fourth well 230, and the fifth well 240 are wells having P-type conductivity, and are doped with P-type impurities such as boron. Therefore, it can be understood that in the second region B, a P-type well is disposed below the N-type well, and the N-type well includes the first well 200 and the second well 210, and the P-type well includes the third well 220 and the fourth well 230. The structure shown in FIG. 2 is an example of a schematic configuration of the semiconductor device 1 according to the embodiment, and there may be a case where the second well 210 does not exist, for example.

At least, the fourth well 230 is substantially in contact with the first insulating portion 144 surrounding the sidewall of the TSV 140. More preferably, both the third well 220 and the fourth well 230 are substantially in contact with the first insulating portion 144 surrounding the TSV 140. The first well 200 and the second well 210 may be spaced apart from the first insulating portion 144. In other words, the first insulating portion 144 is in contact with the third well 220 and the fourth well 230 at the boundary D.

The second region B including the first well 200 and the second well 210 comprises an N-type well region. A P-channel metal-oxide-semiconductor field-effect transistor (MOSFET) having a P-type conductivity (not shown) is disposed on the surface of the first well 200. The third region C including the fifth well 240 comprises a P-type well region. An N-channel metal-oxide-semiconductor field-effect transistor (MOSFET) having an N-type conductivity (not shown) is disposed on the surface of the fifth well 240. For example, a complementary metal oxide semiconductor (CMOS) circuit includes the P-type MOSFET disposed on the first well 200 and the N-type MOSFET disposed on the fifth well 240.

The third well 220 and the fourth well 230 are disposed below the first well 200 and the second well 210. As described below, the concentration of dopant in the fourth well 230 is higher than the concentration of dopant in the third well 220. This provides electrical isolation between each of the first well 200 and the second well 210 and the semiconductor substrate 170. Furthermore, the second well 210 is disposed below the fifth well 240. This provides electrical isolation between the fifth well 240 and each of the third well 220, the fourth well 230, and the semiconductor substrate 170.

Next, an outline of a method for manufacturing the semiconductor device 1 shown in FIG. 2 will be described. The first well 200, the second well 210, the third well 220, the fourth well 230, and the fifth well 240 are formed in the semiconductor substrate 170. The first well 200, the second well 210, the third well 220, the fourth well 230, and the fifth well 240 are formed by implanting ions into the semiconductor substrate 170 using an ion implantation technique and performing a heat treatment for activating impurities. The regions in which the first well 200, the second well 210, the third well 220, the fourth well 230, and the fifth well 240 are formed can be defined by forming a resist mask by a known lithography technique when the ion implantation is performed.

The ion implantation is performed, for example, as follows.

The ion implantation for forming the first well 200 can be performed, for example, using phosphorus as a dopant under a condition of an implantation energy of 200 to 700 keV and a dose of 1.0×10¹² to 1.0×10¹⁴ atoms/cm².

The ion implantation for forming the second well 210 can be performed, for example, using phosphorus as a dopant under a condition of an implantation energy of 600 to 1400 keV and a dose of 1.0×10¹² to 1.0×10¹⁴ atoms/cm².

The ion implantation for forming the third well 220 can be performed, for example, using boron as a dopant under a condition of an implantation energy of 500 to 1100 keV and a dose of 1.0×10¹² to 1.0×10¹⁴ atoms/cm².

The ion implantation for forming the fourth well 230 can be performed, for example, using boron as a dopant under a condition of an implantation energy of 700 to 1500 keV and a dose of 1.0×10¹² to 1.0×10¹⁴ atoms/cm².

The ion implantation for forming the fifth well 240 can be performed, for example, using boron as a dopant under a condition of an implantation energy of 80 to 400 keV and a dose of 1.0×10¹² to 1.0×10¹⁴ atoms/cm².

In the ion implantation for forming the first well 200, a photoresist is formed to cover the regions other than the second region B, and in the ion implantation for forming the fifth well 240, a photoresist is formed to cover the regions other than the third region C. The ion implantation for forming the second well 210, the third well 220, and the fourth well 230 is performed using a photoresist which is opened in the second region B and the third region C.

For example, the ion implantation for forming the first well 200 is performed using phosphorus as a dopant under a condition of an implantation energy of 500 keV and a dose of 5.0×10¹³ atoms/cm², the ion implantation for forming the second well 210 is performed using phosphorus as a dopant under a condition of an implantation energy of 1100 keV and a dose of 2.5×10¹³ atoms/cm², the ion implantation for forming the third well 220 is performed using boron as a dopant under a condition of an implantation energy of 900 keV and a dose of 5.0×10¹² atoms/cm², the ion implantation for forming the fourth well 230 is performed using boron as a dopant under a condition of an implantation energy of 1200 keV and a dose of 1.0×10¹³ atoms/cm², and the ion implantation for forming the fifth well 240 is performed using boron as a dopant under a condition of an implantation energy of 250 keV and a dose of 5.0×10¹³ atoms/cm². In this case, the projected range of the dopant implanted to form the first well 200 is about 0.6 μm, the projected range of the dopant implanted to form the second well 210 is about 1.2 μm, the projected range of the dopant implanted to form the third well 220 is about 1.8 μm, the projected range of the dopant implanted to form the fourth well 230 is about 2.2 μm, and the projected range of the dopant implanted to form the fifth well 240 is about 0.6 μm.

After the ion implantation and the activation processing described above are performed, the concentration of the dopant in the first well 200 is higher than the concentration of the dopant in the second well 210, and the concentration of the dopant in the fourth well 230 is higher than the dopant concentration in the third well 220. Note that the concentration of the dopant in the semiconductor substrate 170 is lower than the concentrations of the dopants in the third well 220, the fourth well 230, and the fifth well 240.

As a result, as shown in FIG. 2, a structure is formed in which the first well 200 and the fifth well 240 are arranged at the top portion of the semiconductor substrate 170 so as to be adjacent to each other, and the second well 210, the third well 220, and the fourth well 230 are arranged downwards in this order below the first well 200 and the fifth well 240. The first well 200, the second well 210, the third well 220, and the fourth well 230 are adjacent to the upper portion of the TSV 140. The condition for the ion implantation described above is set in consideration of the latch-up characteristics, the electrical characteristics of elements to be formed in each well, etc.

Next, the second insulating portion 180 is formed so as to cover the top surface of the semiconductor substrate 170. Next, a through-hole 145 which penetrates the second insulating portion 180 and the semiconductor substrate 170 in the up-down direction is formed in the first region A, and the first insulating portion 144 is formed on the side surface of the through-hole 145. Next, the TSV 140 is formed by forming a conductive material inside the through-hole 145. The second insulating portion 180 and the semiconductor device 1 are formed, for example, by forming a film of an insulating material such as silicon dioxide using a chemical vapor deposition (CVD) technique. The TSV 140 is formed, for example, by depositing a conductive material such as copper (Cu) inside the first insulating portion 144 of the through-hole 145 using, for example, a plating technique.

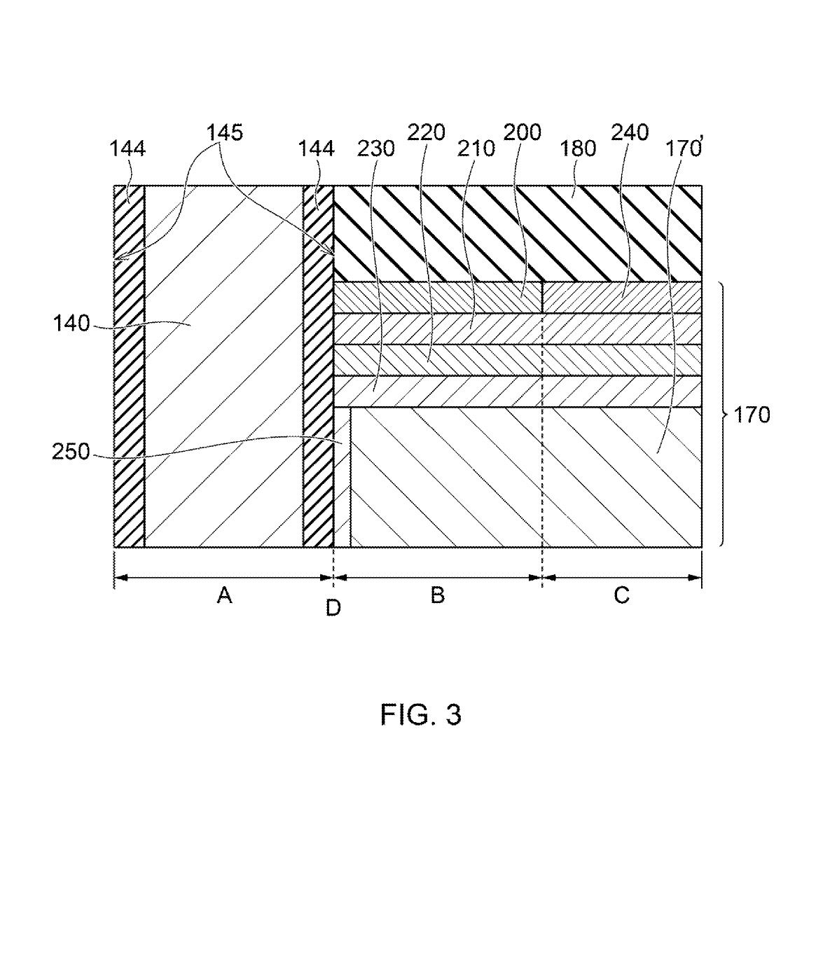

The semiconductor device 1 normally operates at a voltage of, for example, about 0 to 5.0 volts. A voltage of about 0 to 5.0 volts is normally applied to the TSV 140. Here, for example, when a voltage of about 3.0 to 5.0 volts is applied to the TSV 140, an inversion layer 250 may be formed in the semiconductor substrate 170 facing the TSV 140 via the first insulating portion 144 as shown in FIG. 3 because the semiconductor substrate 170 is doped with P-type impurities.

Here, assuming that the fourth well 230 does not exist, the inversion layer 250 may cross the third well 220 and connect to the second well 210. When the inversion layer 250 and the second well 210 are connected to each other, electrons which are majority carriers in the first well 200 and the second well 210 are supplied to the inversion layer 250. Therefore, even when a high-frequency signal is applied to the TSV 140, electrons are supplied to the inversion layer 250 in response to the frequency of the signal applied to the TSV 140, so that the parasitic capacitance value between the TSV 140 and the semiconductor substrate 170 increases. When the parasitic capacitance value between the TSV 140 and the semiconductor substrate 170 increases, the transfer speed of the signal to be applied to the TSV 140 decreases, which eventually decreases the operation speed of the semiconductor device 1 and increases the power consumption of the semiconductor device 1. In order to improve the operation speed of the semiconductor device 1 and reduce power consumption, it would be better not to arrange the second region B, that is, an N-type well formation region adjacently to the surroundings of the TSV 140. However, this reduces the degree of freedom in circuit layout design and makes it difficult to effectively utilize the area of the top surface of the semiconductor substrate 170 on which the circuit is formed.

However, in the semiconductor device 1 according to the embodiment, the fourth well 230 exists under the third well 220. Therefore, the inversion layer 250 is prevented from crossing the fourth well 230 and the third well 220 and connecting to the second well 210. In this state, when a high-frequency signal is applied to the TSV 140, electrons which are minority carriers cannot follow the high-frequency signal in the semiconductor substrate 170 doped with P-type impurities. Therefore, electrons are not sufficiently supplied to the inversion layer 250, which only leads to an expansion of a depletion layer around the inversion layer 250, and the parasitic capacitance value between the TSV 140 and the semiconductor substrate 170 does not increase. In other words, by providing the fourth well 230, even when the second region B, that is, the N-type well region is arranged to be adjacent to the TSV 140, it is possible to restrict the increase in the parasitic capacitance value of the TSV 140. Therefore, the semiconductor device 1 according to the present embodiment can contribute to an improvement in the operating speed, reduction of power consumption, an improvement in the degree of freedom in circuit layout design, and effective utilization of the surface of the semiconductor substrate 170.

As above, DRAM is described as an example of the semiconductor device according to the embodiment, but the above description is merely one example and not intended to be limited to DRAM. Memory devices other than DRAM, such as static random-access memory (SRAM), flash memory, erasable programmable read-only memory (EPROM), magnetoresistive random-access memory (MRAM), and phase-change memory for example can also be applied as the semiconductor device. Furthermore, devices other than memory, including logic ICs such as a microprocessor and an application-specific integrated circuit (ASIC), for example, are also applicable as the semiconductor device according to the foregoing embodiment.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a substrate having a first conductivity type;
a through-silicon via going through from a top surface to a bottom surface of the substrate;
an insulating film surrounding a side surface of the through-silicon via;
a first well having a second conductivity type in a top portion of the substrate; and
a second well having the first conductivity type just below the first well in the substrate;
wherein one side of the first well and the second well is substantially in contact with the insulating film.

2. The apparatus of claim 1, wherein the second well is divided into an upper well portion and a lower well portion, and a dopant concentration of the lower well portion of the second well is greater than that of the upper well portion of the second well.

3. The apparatus of claim 2, wherein the first well is divided into an upper well portion and a lower well portion, and a dopant concentration of the upper well portion of the first well is greater than that of the lower well portion of the first well.

4. The apparatus of claim 3, further comprising a first metal-oxide-semiconductor field-effect transistor having a first conductivity channel type and provided on an upper surface of the upper well portion of the first well.

5. The apparatus of claim 4, further comprising a third well adjacent to the upper well portion of the first well and just above the lower well portion of the first well.

6. The apparatus of claim 5, further comprising a second metal-oxide-semiconductor field-effect transistor having a second conductivity channel type and provided on an upper surface of the third well.

7. An apparatus comprising:
a substrate having a first conductivity type;
a first region in the substrate, the first region including a through-silicon via going through from a top surface to a bottom surface of the substrate and an insulating film surrounding a sidewall of the through-silicon via; and
a second region adjacent to the first region in the substrate, the second region including a first well having a second conductivity type in a top portion of the substrate, and a second well having the first conductivity type just below the first well in the substrate;
wherein one side of the first well and the second well is substantially in contact with the insulating film at a border between the first region and the second region.

8. The apparatus of claim 7, wherein the second well is divided into an upper well portion and a lower well portion, and a dopant concentration of the lower well portion of the second well is greater than that of the upper well portion of the second well.

9. The apparatus of claim 8, wherein the first well is divided into an upper well portion and a lower well portion, and a dopant concentration of the upper well portion of the first well is greater than that of the lower well portion of the first well.

10. The apparatus of claim 9, further comprising a first metal-oxide-semiconductor field-effect transistor having a first conductivity channel type and provided on an upper surface of the upper well portion of the first well.

11. The apparatus of claim 10, further comprising a third well having the first conductivity type adjacent to the upper well portion of the first well and just above the lower well portion of the first well.

12. The apparatus of claim 11, further comprising a second metal-oxide-semiconductor field-effect transistor having a second conductivity channel type and provided on an upper surface of the third well.

13. An apparatus comprising:
a substrate having a first conductivity type;
a through-silicon via going through from the top surface to the bottom surface of the substrate;
an insulating film surrounding a sidewall of the through-silicon via;
a first well having a second conductivity type in a top portion of the substrate; and
a second well just below the first well in the substrate, the second well having the first conductivity type, the second well divided into an upper well portion and a lower well portion;
wherein a dopant concentration of the lower well portion of the second well is greater than that of the upper well portion of the second well; and
wherein one side of the lower well portion of the second well is substantially in contact with the insulating film.

14. The apparatus of claim 13, wherein the first well is divided into an upper well portion and a lower well portion, and a dopant concentration of the upper well portion of the first well is greater than that of the lower well portion of the first well.

15. The apparatus of claim 14, wherein the first conductivity type is P-type, and wherein the second conductivity type is N-type.

16. The apparatus of claim 15, further comprising a P-channel metal-oxide-semiconductor field-effect transistor provided on an upper surface of the upper well portion of the first well.

17. The apparatus of claim 16, further comprising a third well having the first conductivity type, adjacent to the upper well portion of the first well and just above the lower well portion of the first well.

18. The apparatus of claim 17, further comprising an N-channel metal-oxide-semiconductor field-effect transistor provided on an upper surface of the third well.

19. The apparatus of claim 18, wherein one side of the upper well portion of the second well is substantially in contact with the insulating film.

20. The apparatus of claim 19, wherein one side of the upper and lower wells of the first well is substantially in contact with the insulating film.
